(19) United States
(12) Patent Application Publication
(10) Pub. No.: US 2006/0006526 A1
(43) Pub. Date: Jan. 12, 2006

(54) Thermal interposer for cooled electrical packages

(76) Inventors: John M. Coronati, Allentown, PA (US); Gustav Edward Derkits JR., New Providence, NJ (US); David Daugherty, Allentown, PA (US); Christopher Fuchs, Exton, PA (US); John M. Geary, Macungie, PA (US); David J. Lischner, Allentown, PA (US)

Correspondence Address: Law Office of Peter V.D. Wilde, 301 East Landing, Williamsburg, VA, 23185, US

(21) Appl. No.: 10/885,271

(22) Filed: Jul. 6, 2004

(51) Int. Cl. H01L 23/34

(52) U.S. Cl. 257/720

(57) ABSTRACT

The specification describes electrical assemblies comprising actively cooled components wherein a thermal interposer is used to limit heat transfer between the ambient and the cooled components. The thermal interposer is effective for transmitting signals for both power/ground and RF. Structurally, the thermal interposer comprises thin conductors in various configurations that convey electrical signals but significantly limit heat flow.

### FIELD OF THE INVENTION

This invention relates to electronic device packages in which one or more components is actively cooled.

### BACKGROUND OF THE INVENTION

Some types of devices used in electronic circuit packages require controlled temperature to avoid degradation, failure, or to meet functional requirements. Common among these are semiconductor laser packages where the lifetime of the laser diode is significantly enhanced if the diode is maintained at a moderate uniform temperature, typically below 40° C. Accordingly, these devices are often provided with active cooling elements, usually thermoelectric cooling (TEC) devices. Normally, they are also hermetically sealed to provide additional environmental control. Common hermetic packages comprise a sealed ceramic and/or metal container in a box-like configuration. The I/O leads pass through holes in the container walls, and are sealed with welding, epoxy, solder, or other suitable seal. In the description below these device packages are referred to as TEC packages. The primary device category of interest for TEC packages are optoelectronic device TEC packages.

A typical TEC package contains a variety of components. The most temperature sensitive devices are cooled using the TEC. These are referred to here as cooled components. Other components in the package may not require cooling. Thus the TEC package may have one or more sections where the TEC cooling is focused.

The environments in which these packages are used varies widely, and adverse or hostile environments are not uncommon. Most customer specifications require the devices to operate effectively in relatively hot temperature environments, e.g. as high as 75 or 80° C. The need for active cooling of heat sensitive components in a package exposed to these temperatures is well established. Also the potential for heat flow from the ambient to the interior of the package and the thermally sensitive devices in the package increases dramatically with such large differentials. Large temperature differentials between the ambient and the cooled components lead to both increases in thermoelectric cooling power, and larger TEC refrigerators. While both are normally manageable, neither is desirable.

### BRIEF STATEMENT OF THE INVENTION

We have recognized two important qualities of TEC packages designed for high temperature environments. First, a large fraction of the heat flow from the ambient to the TEC part of the package is conveyed by conduction through the wire bonds that interconnect the cooled components to the pins that extend through the TEC package wall, and interconnect the devices in the TEC package to the outside. Second, extreme thermal loads on the TEC package, due to conditions in the use environment, are frequently transient. Thus we have designed a TEC package with a thermal interposer that limits heat transfer between the ambient and the cooled components. It also is effective for transmitting signals for both power/ground and RF signals. Structurally, the thermal interposer comprises thin conductors in various configurations that convey electrical signals but significantly limit heat flow.

### BRIEF DESCRIPTION OF THE DRAWING

The invention may be better understood when considered in conjunction with the drawing in which:

FIG. 1 is a plan view of a portion of an illustrative TEC package of the prior art;

FIG. 2 is a section view of a thermal interposer according to one embodiment of the invention;

FIG. 3 is a section view across the width of the interposer of FIG. 2, and comparing the cross section of the thermal interposer with the cross section of a typical wire bond wire;

FIG. 4 is a plan view similar to the view of FIG. 1 showing the placement of the thermal interposer of the invention; and

FIG. 5 is an illustration of an interposer adapted for a single wire bond interconnection.

### DETAILED DESCRIPTION OF THE INVENTION

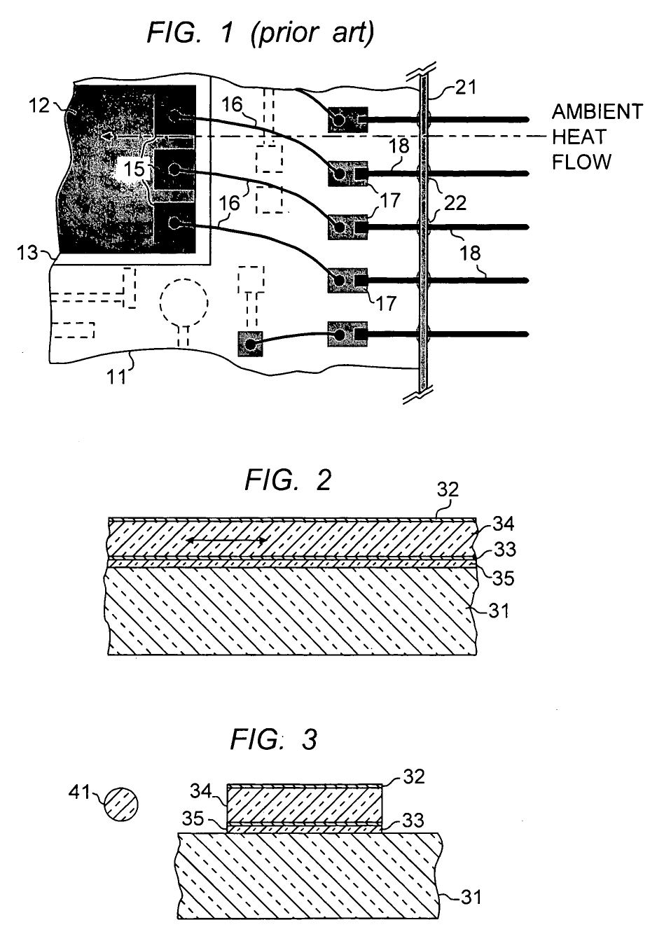

FIG. 1 shows an example of a prior art optoelectronic TEC package where the substrate 11 is a plan view of a larger package, and shows a portion of the cooled component 12. Other components, not part of the invention, are shown in phantom. The TEC element is shown at 13, with the cooled component 12 mounted on the TEC element. The cooled component in an optoelectronic package is most typically a laser diode, possibly with support circuitry. In the package shown, the laser diode is modulated with an RF signal, and the RF connections are split into multiple wire bond interconnections, with bond pads 15, and wire bonds 16, shown in the figure. The RF signal interconnection is split into multiple wire bond interconnections to reduce inductance and help provide a controlled impedance. The three bond pads 15 may be on the cooled component, or, more typically, on a support assembly associated with the cooled component. The wire bonds 16 attach to bond pads 17 that are associated with pins 18. The pins and package traces extend through wall 21 of the TEC package. As indicated, the wall 21 in the figure is only a portion of one wall of the TEC package. The pin openings in the wall are sealed with brazing, solder, epoxy, laser welds, or other suitable means 22. An example of the type of package illustrated in FIG. 1 is a 14 pin butterfly package. For the purpose of illustrating the invention only the RF leads to the cooled component are shown in detail.

As mentioned above, we have recognized that a large portion of the heat flow from the ambient to the cooled component 12 (represented by the arrow in FIG. 1) traverses a path from wall 21 and pins 18 through the wire bonds 16, to the cooled component 12. We limit the heat transfer through this flow path by placing the thermal interposer of the invention in this heat flow path.

FIG. 2 shows a section view of the thermal interposer. The section is a longitudinal section, i.e. taken parallel to the direction of heat flow and current flow (arrow). It will be appreciated that the thermal interposer may have any one of a variety of structural designs. Shown here is an embodiment wherein a substrate 31 supports a laminate of two thin conductors 32 and 33, bonded to an intermediate insulating layer 34 with a bonding layer 35. The insulating layer in this embodiment is preferably a polymer, such as polyimide, polyethylene, polyester, polyacrylate. The thickness of layer 34 may be, for example, 5-50 mils. The thin conductors may comprise any suitable conductor, and will normally consist of a metal such as Cu or Au. However, a variety of conductive materials may be chosen, including Ni, Ag, Ti, Ta, TiN, TaN, silicides, alloys, composite or layered conductors, etc. The bonding agent may be, for example, epoxy. The substrate may be a rigid or flexible polyimide or other relatively poorly thermally conducting material. The laminate structure shown here is common in two sided flexible printed circuit boards, and suitable layer materials and laminating methods are well known in the art. As mentioned, a variety of structural and material alternatives exist for the thermal interposer. For example, the whole assembly shown in FIG. 2 may comprise a laminate, in a manner that eliminates the need for bonding layer 35.

A description of simple printing techniques for forming thin film laminates may be found in: Kumar and Whitesides, “Features of Gold Having Micrometer to Centimeter Dimensions Can Be Formed Through a Combination of Stamping with an Elastomeric Stamp and an Alkanethiol ‘Ink’ Followed by Chemical Etching,” APPL. PHYS. LETT. Vol. 63 (1993), at p. 2002; Xia, Qin, and Whitesides, “Microcontact Printing With a Cylindrical Rolling Stamp: A Practical Step Toward Automatic Manufacturing of Patterns with Submicrometer-Sized Features,” ADV. MATER. Vol. No. 12 (1996), at p. 1015. Standard printed circuit board techniques are also useful for forming the thin conductors of the thermal interposer. See for example “Printed Circuit Board Material Handbook”, Martin Jawitz, McGraw-Hill. For details on fabrication techniques for thin conductors on polymer substrates, and other relevant matters, these teachings are incorporated herein by reference.

As an alternative to the polymer substrate and/or laminate, the interposer may comprise a rigid substrate, such as ceramic or epoxy printed wiring board, a deposited metal film, for example Au, Cu, a deposited insulating film, for example SiO₂, and a second deposited metal film. Any suitable method may be used to construct the thin conductors, and the details of such method are not part of this invention.

The example illustrated in FIGS. 2 and 3 is for an RF conductor with two RF thin conductors 32 and 33, and three wire bond interconnections to each RF conductor. Other thin conductor structures would be suitable for single RF conductor planes, where either layer 32 or 33 could be eliminated, or for single power/ground runners. Two RF conductor planes may be situated side-by-side on a single planar layer, rather than on the top and bottom of a separating layer as shown in FIG. 2.

FIG. 3 shows the thermal interposer of FIG. 2 in a cross section though the width of the interposer. In this view the aspect ratio of width to thickness is evident. A function of the thermal interposer is to reduce the heat transfer rate from the ambient to the cooled component(s). This is achieved by making the thermal cross section of the interposer small, while making the conductor relatively long in the direction of heat flow, within the limitations of the overall size and organization of the package. At the same time the thin conductors in the interposer are sufficient to carry RF signals to the cooled component. This normally requires that the thin conductors have a thickness just sufficient to exceed the skin depth of the RF signal.

Taking both considerations into account, it is recommended that the thin conductors 32 and 33 be in the range 0.5 to 10 microns thick, and preferably 1.0 to 6 microns thick. In addition, it is recommended that the thin conductors 32 and 33 have a cross section width in the range 1-40 mils, and preferably 1-20 mils. This width is sufficient for wire bonding at least one wire bond interconnection to the ends of the interposer. The length of the interposer may be whatever is convenient for the required interconnection. Since the main function of the thermal interposer is to reduce the heat transfer rate between the ambient outside the TEC package and the cooled components, and the heat transfer rate is mainly a function of the thermal cross section available for heat flow and the length along the heat flow path, the thermal interposer may be designed with a wide choice of dimensions.

Moreover, the heat flow restriction created by the interposer will cause the heat distribution in the TEC package to change. Where there is a significant difference in temperature between the ambient and the design temperature of the cooled component, the heat that is prevented from reaching the cooled component “backs up” in the interposer, and in any substrate and interconnections between the interposer and the wall of the TEC package. This will cause the temperature in that portion of the package to rise, and indicates that the interposer is functioning as desired. The redistribution of heat in the TEC package allows the TEC element to maintain the cooled component at the desired temperature where, otherwise, if a larger heat flow rate is allowed through continuous wire bonds (i.e. in the absence of the interposer), the TEC would be challenged. Thus the interposer reduces the heat load on the TEC element(s).

With this discussion in mind, it will be evident that the interposer may be placed at any point in the conductor path between the external pins that extend through the wall of the TEC package and the cooled component.

For a variety of reasons, the length of the wires used for wire bond interconnections is usually minimized. This imposes some constraints on the design layout. It is observed that where the interposer is used, as a partial replacement for the wire bond, i.e. for a length less than the wire bond interconnection, or for a one-for-one replacement of the length, these design constraints are removed. Moreover, the ability of the interposer to span lengths beyond those usually assigned to wire bond interconnections, adds to the design freedom of the package designer.

Wire bonds are typically designed with a length below 10 mils to avoid impairing the signal. At high frequencies the design length of the wire may be even further reduced. The same constrain does not apply to the thermal interposer of the invention. Thus, conductor lengths in excess of 10 mils, for example 15 mils or greater, may be used.

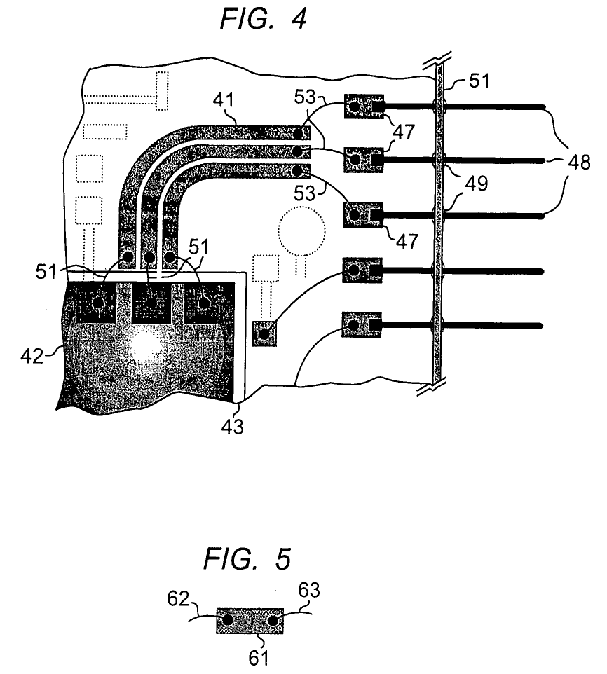

An example of a thermal interposer layout is shown in FIG. 4. The interposer is shown at 41, and comprises an elongated runner that curves through 90° in this example. FIG. 4 is intended to indicate use of the interposer for spanning required distances in the layout, as well as simple routing. The cooled component, here a laser for an optoelectronic device assembly, is shown at 42, with three bond pads for three wire bond interconnections. The three bond pads may be on the cooled component, or on a support assembly associated with the cooled component. The TEC element is shown at 43, beneath the cooled component. The wall of the hermetic TEC package is shown at 51, with pins 48 extending through the wall and attached to pads 47. The resemblance of this TEC package to that of FIG. 1 is evident. In the embodiment of FIG. 4, the objective, according to the invention, is to replace wire bonds 16 in FIG. 1, or at least a portion of those wire bonds, with interposer 41. The interposer 41 is attached to the cooled component assembly with wire bonds 51, and to pads 47 and pins 48 with wire bonds 53. Seals where the pins extend through wall 51 are shown at 49.

As suggested earlier, the three wire bond interconnection scheme of FIGS. 1 and 4 is an example of a split RF interconnection. The interposer of the invention may also be used to replace single wire bonds in the manner shown in FIG. 5. Here the interposer 61, one of the thin conductor elements as described above, is wire bonded with single wire bonds 62 and 63 at each end.

A typical wire used in conventional wire bond interconnections is shown at 40, in cross section, in FIG. 3, and provides a visual comparison of the cross section area of a typical wire with the cross section area of thin conductors 12 and 13 in FIG. 3. The width of the elements in FIG. 3 is approximately to scale (the thickness of metal layers 12 and 13 is exaggerated for clarity). A typical wire for a wire bond has a diameter of 1 mil, and a thermal cross section of approximately 0.8 mils². In the arrangement shown in FIGS. 1 and 4, where three wire bonds connect the cooled component to the TEC package wall, the total thermal cross section is 2.4 mils². By way of comparison, thin conductors for the interposer that have the dimensions recommended earlier will generally have a cross section of less than 1.0 mils², and in many cases less than 0.7 mils².

A characteristic of the embodiments shown above is that the interposer is interconnected at each end with two or more wire bonds, and replaces at least a portion of one wire bond. In some TEC package designs, and for some interposer designs, it may be found convenient to interconnect the interposer directly to runners in the rest of the circuit using, for example, surface mount technology, where solder pillars replace wire bonds. In some cases, the interposer may be interconnected at one end with wire bonds, and at the other end with another form of interconnection. Usually, the interposer will have at least one wire bond interconnection.

The term TEC is used repeatedly in this description but it will be understood that any kind of cooling device may be used in place of, or in addition to, a thermoelectric element. As mentioned before, the term cooled component is intended as meaning any electrical component that has an active cooling element(s) associated therewith. A cooled component package is a cooled component in a container housing. The package may comprise one or more TEC elements.

Various additional modifications of this invention will occur to those skilled in the art. All deviations from the specific teachings of this specification that basically rely on the principles and their equivalents through which the art has been advanced are properly considered within the scope of the invention as described and claimed.

1. A cooled component package comprising:
a. a cooled component,
b. a container housing the cooled component, the container comprising a container wall,
c. at least one electrical interconnection extending between the container wall and the cooled component,
d. a thermal interposer in the electrical connection, the thermal interposer comprising a thin conductor.

2. The cooled component package of claim 1 wherein the thin conductor is an elongated runner interconnected with at least one wire bond.

3. The cooled component package of claim 2 wherein the electrical interconnection comprises wire bonds to both ends of the elongated runner.

4. The cooled component package of claim 1 wherein the cooled component is an optoelectronic device.

5. The cooled component package of claim 4 wherein the cooled component is a laser.

6. The cooled component package of claim 2 wherein the thin conductor has a thickness in the range 0.5-10 microns.

7. The cooled component package of claim 6 wherein the thin conductor has a thickness in the range 1.0-6 microns.

8. The cooled component package of claim 6 wherein the thin conductor has a cross section width in the range 1-40 mils.

9. The cooled component package of claim 7 wherein the thin conductor has a cross section width in the range 1-20 mils.

10. The cooled component package of claim 1 wherein the thermal interposer comprises a two layer laminate of metal-polymer.

11. The cooled component package of claim 1 wherein the thermal interposer comprises a three layer laminate of metal-polymer-metal.

12. The cooled component package of claim 11 wherein the three layer laminate of metal-polymer-metal is supported by a flexible polymer substrate.

13. The cooled component package of claim 1 wherein the thin conductor comprises copper.

14. The cooled component package of claim 2 wherein the cross section area of the elongated runner is less than 0.5 mils².

15. The cooled component package of claim 11 wherein the electrical interconnection comprises wire bonds to both of the two metal layers of the three layer laminate of metal-polymer-metal.

16. The cooled component package of claim 2 wherein the electrical connection comprises a single wire bond attached to each end of the elongated runner.

17. The cooled component package of claim 2 wherein the electrical connection comprises at least two wire bonds attached to each end of the elongated runner.

18. The cooled component package of claim 1 wherein the length of the interposer is greater than 10 mils.
